(19) United States
(12) Patent Application Publication
(10) Pub. No.: US 2007/0159224 A1
(43) Pub. Date: Jul. 12, 2007

(54) Duty-cycle correction circuit for differential clocking

(76) Inventors: Amar Dwarka, Raleigh, NC (US); Joseph Marsh Stevens, Morrisville, NC (US)

Correspondence Address: DILLON & YUDELL LLP, 8911 N. CAPITAL OF TEXAS HWY.,, SUITE 2110, AUSTIN, TX, 78759, US

(21) Appl. No.: 11/314,909

(22) Filed: Dec. 21, 2005

(51) Int. Cl. H03K 3/017

(52) U.S. Cl. 327/175

(57) ABSTRACT

A completely differential approach to correcting duty-cycle distortions of a differential clock signal propagating through a differential amplifier. A duty-cycle distortion correction (DCDC) differential amplifier circuit/device is provided with a differential amplifier whose output wires are coupled to a correction circuit. The correction circuit comprises a differential low pass filter and a differential correction amplifier. The differential correction amplifier's output is dotted back into the output of the amplifier. The differential output of the amplifier is passed through the low pass filter, which provides differential DC output signals that triggers respective correction amplifier transistors to generate an inverted correction current that is added back to respective differential output pulse. The DCDC differential amplifier provides a completely differential approach to correction of duty-cycle distortions within the differential output.

### BACKGROUND OF THE INVENTION

1. Technical Field

The present invention relates generally to electrical circuit devices and specifically to signal propagation through electrical circuit devices. Still more particularly, the present invention relates to a method and circuit device for correcting duty-cycle distortion in signals propagating through electrical circuit devices.

2. Description of the Related Art

Duty-cycle in electrical circuit devices is a measure of the up pulse time versus the cycle period time for a clock signal propagating through the device. With many current device implementations, these clock signals are differential clock signals (rather then single ended clock signals), and tend to exhibit distortions in their duty-cycle as they propagate through the device.

Conventional circuit devices, such as ASICs (application-specific integrated circuits), for example, receive and propagate differential clock input signals with an up and down pulse via differential clock trees made up of a sequence of amplifiers (or clock buffers). These devices are bandwidth-limited and thus frequently experience a problem with duty-cycle distortion. This distortion is due to the fact that the clock trees are made with serial differential amplifier stages (or buffers) that have/exhibit bandwidths close to the clock frequency they are buffering. This distortion may also occur due to the large distance between amplifier stages (buffers) and the lowering of the amplifier bandwidth due to parasitic wiring capacitance. Each amplifier stage causes some amounts of distortion in the propagating clock signal, as illustrated by FIG. 1.

As shown by FIG. 1, the input clock signal 110a period is comprised of two pulses, a first pulse 111 and a second pulse 112, which are on for different fractions of the clock cycle period. Input clock signal 110a propagates through a sequence of amplifiers (clock buffers) 105. As the pulses 111 and 112 propagate through each buffer 105, the first pulse 111, which (relative to the second pulse 112) initially has a shorter pulse time (equivalently higher frequency) and lower magnitude decreases in magnitude, while the second pulse 112, which initially has a longer pulse time (lower frequency) and greater magnitude increases in magnitude. This parallel increase and decrease in pulse times and magnitudes further distorts the duty-cycle of propagating clock signal 110b/110c.

With these distortions adversely affecting the efficiency of these devices, two designs have been proposed to attempt to reduce the amount of duty-cycle distortions at each stage of propagation. Correction at each stage is implemented since if the duty-cycle is corrected at each stage, the drive distance (between stages) may be increased and the required bandwidth of the differential amplifiers is lowered. The first design involves changes or adjustments to traditional amplifier design while the second design involves adjustments to the output signal via single-ended feedback.

FIG. 2 illustrates the first design by which additional impedance 210 (illustrated as a resistor in parallel with a capacitor) are added to the standard amplifier circuit to produce an equalization amplifier 200. The additional impedance 210 within equalization amplifier 200 adds high frequency peaking to a standard differential amplifier so that the high frequency (lower magnitude) pulse-widths are amplified more than the low frequency (higher magnitude) pulse-widths. The degeneration resistor (R within impedance 210) takes the DC gain down while the high frequency gain stays constant as R increases. There is also less gain for low frequency and greater gain for high frequency to correct the duty-cycle.

As illustrated by the accompanying chart 220, the addition of peaking allows the high frequency portion of the clock cycle to increase in magnitude while the lower frequency portion of the clock cycle decreases in magnitude. The chart 220 illustrates the gain over frequency utilizing the design of FIG. 2. The dashed curve 225 shows the response when the clock signal is passed through the standard/normal amplifier design, while the solid curve 230 illustrates the adjustment that occurs with the addition of impedance 210. Notably, while this design does provide some correction to the distortions seen by the particular circuit illustrated, this high frequency peaking option generally does not work over a wide range of clock frequencies and amplifier designs. This design is therefore not a robust design as the peaking must be tuned to a fixed frequency.

The second design involves the addition of a single-ended feedback to the differential amplifier, by which the duty-cycle of the amplifier output is analyzed and then the amplifier circuit is adjusted (by feedback input) to correct the duty-cycle. The feedback method for duty-cycle correction is normally used on rail-to-rail, single-ended buffer circuits (i.e., complementary inputs) and involves a single-ended feedback. FIG. 3 illustrates one such feedback circuit. As shown, reference voltage (Vref) 315 is created with a voltage divider of supply voltage (VDD) 310 and fed into amplifier 306 as a first input. Amplifier 306 receives single-ended error signal 335 as its second input, and generates feedback voltage 325. Single-ended error signal 335 is created by filtering the output of replica clock buffer 320 with low-pass filter 330 to produce a DC component of the clock signal (LPF input). Single-ended feedback voltage 325 is sent to both clock buffer 305 and replica clock buffer 320 to offset adjustments to clock input 300 as clock input 300 passes through clock buffer 305. Using single-ended feedback signal 335, the switching threshold of buffer 305 is adjusted so that buffer 305 switches at a voltage that outputs closer to a 50/50 duty-cycle.

The above single-ended feedback approach is utilized by several prior art references in a variety of applications. For example, U.S. Pat. No. 5,315,164 corrects a single-ended clock by adding in an error current to an incoming clock to change the switching threshold based on a measurement of averages of the single-ended circuit with a single-ended error current is single-ended. U.S. Pat. No. 5,896,053 utilizes a single-ended to complementary converter to create a true and complement clock signals, which are low-pass filtered to give an average DC level for each. The average signals are fed into an error amplifier that produces a single-ended error voltage, which is fed back to a voltage-controlled pulse-width modulator block that adjusts the duty-cycle.

As described above, conventional feedback approach utilizes single-ended circuit feedback. The above design, for example, changes the biasing of the inverter to make the output pulse width smaller or larger by passing a single plus or minus current to the inverter (i.e., adding or subtracting the single error current). These single-ended feedback circuits are, however, prone to noise and requires additional circuitry to convert between differential and single-ended signaling. Additionally, this design requires a large area due to the use of a replica and other feedback conversion mechanisms. Overall, these circuits have inherent problems with poor noise rejection, duty-cycle distortion, higher power, and increased area.

### SUMMARY OF THE INVENTION

Disclosed is a circuit design and method for correcting duty-cycle distortions of a differential clock signal propagating through a differential amplifier (or clock buffer). A correction circuit is coupled to both (differential) output pulses/signals from the differential amplifier. The correction circuit comprises a differential low pass filter, which filters out the DC components of each output pulse/signal of the differential output, and a differential error amplifier, which compares the DC outputs from the low pass filter and generates a pair of differential error-adjustment DC currents. The differential error-adjustment DC currents are then fed back into the respective pulses of the differential output, where the duty-cycle of the differential output is corrected by adding the differential error-adjustment DC currents to respective pulses signals of the differential output. The duty-cycle distortion correction (DCDC) amplifier provides a completely differential approach to correction of duty-cycle distortions within the differential output.

The above as well as additional objectives, features, and advantages of the present invention will become apparent in the following detailed written description.

### BRIEF DESCRIPTION OF THE DRAWINGS

The invention itself, as well as a preferred mode of use, further objects, and advantages thereof, will best be understood by reference to the following detailed description of an illustrative embodiment when read in conjunction with the accompanying drawings, wherein:

FIG. 1 is a prior art representation of distortions in duty-clock cycles for clock signals propagating through a series of clock buffers;

FIG. 2 is a circuit diagram of an equalization amplifier and associated chart showing adjustments to gain versus frequency curve to counter distortions in duty-cycle according to the prior art;

FIG. 3 is a circuit diagram of a single-ended feedback mechanism to correct distortions in duty-cycle for a single ended or complementary buffer, according to the prior art;

FIG. 4 is a circuit diagram illustrating a differential feedback correction circuit which corrects distortions of a differential amplifier's duty-cycle according to one embodiment of the invention; and

FIG. 5 is a propagation flow diagram illustrating the flow of differential clock outputs from a differential amplifier through the differential feedback correction circuit of FIG. 4 to generate a differential feedback in accordance with one embodiment of the invention.

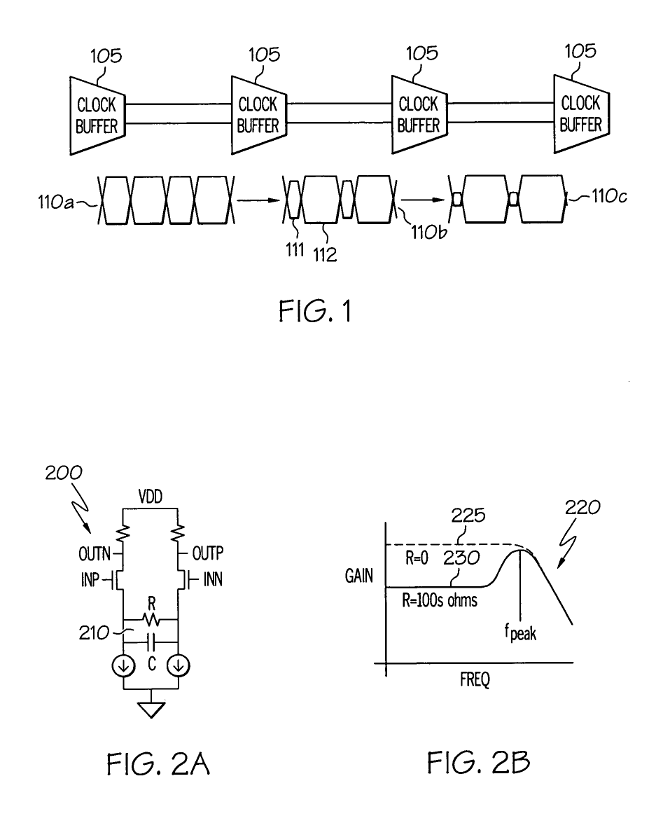

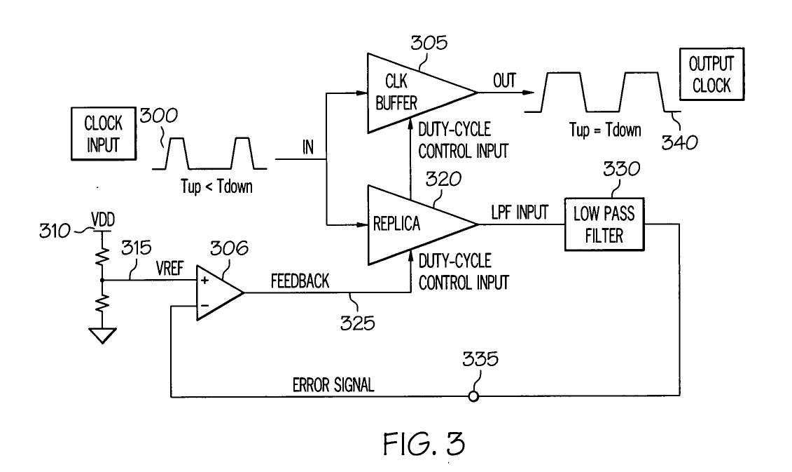

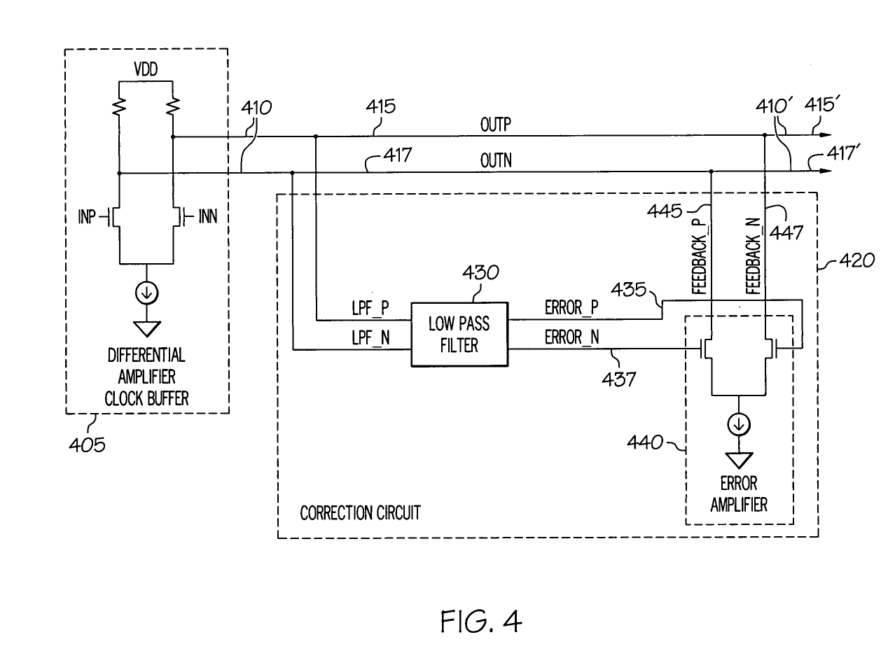

### DETAILED DESCRIPTION OF AN ILLUSTRATIVE EMBODIMENT

The present invention provides a circuit design and method for correcting duty-cycle distortions of a differential clock signal propagating through a differential amplifier (or clock buffer). The circuit devices utilized include a differential amplifier, low-pass filter, and correction current source, which are combined into a simple two stage amplifier circuit with a correction output that is dotted to the differential output of a differential buffer.

A correction circuit is coupled to both (differential) output pulses/signals from the differential amplifier. The correction circuit comprises a differential low pass filter, which filters out the DC (direct current) components of each output pulse/signal of the differential output, and a differential error amplifier, which compares the DC outputs from the low pass filter and generates a pair of differential error-adjustment DC currents. The differential error-adjustment DC currents are then fed back into the respective pulses of the differential output, where the duty-cycle of the differential output is corrected by adding the differential error-adjustment DC currents to respective pulses signals of the differential output. The combination of the amplifier and correction circuit is referred to as a duty-cycle distortion correction (DCDC) differential amplifier to distinguish the DCDC differential amplifier configuration from convention amplifier correction circuits which provide only single-ended feedback correction currents.

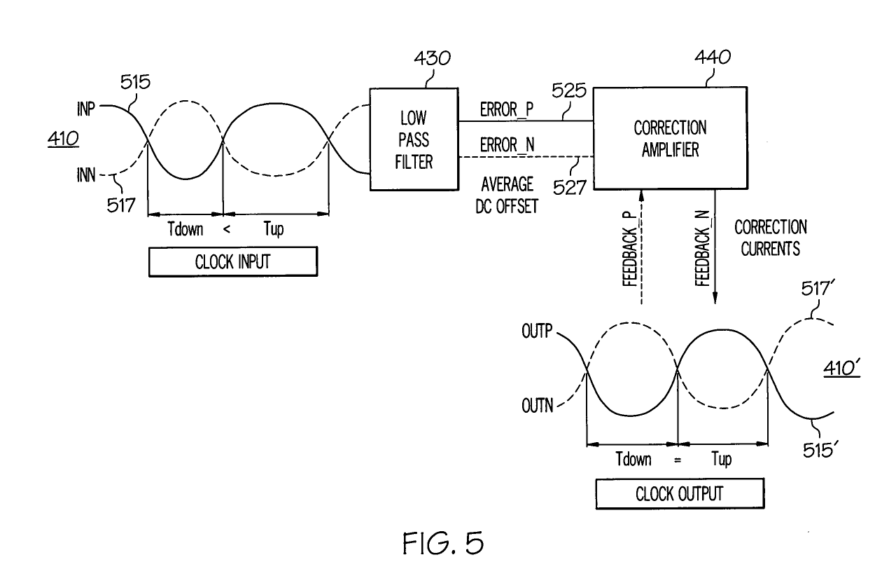

Within the descriptions of the figures, similar elements are provided similar names and reference numerals throughout the figure(s). Where a later-described figure utilizes an element in a different context or with different functionality, the element is provided a different leading numeral representative of the figure number (e.g., 4xx for FIGS. 4 and 5xx for FIG. 5). The specific numerals assigned to the elements are provided solely to aid in the description and not meant to imply any limitations (structural or functional) on the invention.

Referring now to the figures, FIG. 4 illustrates an exemplary DCDC differential amplifier design implementing a “completely differential” feedback system for duty-cycle correction according to one embodiment of the invention. The circuit is designed with two main components, a differential amplifier (or clock buffer) 405 and a correction circuit 420, collectively forming the DCDC differential amplifier 400. Clock buffer 405 provides an output of differential clock signals on differential output clock wires 410. This pair of output signals, OUTP 415 and OUTN 417 propagate on differential output clock wires 410. For clearer understanding of the figures, these output signals named OUTP 415 and OUTN 417, respectively represent the positive phase and negative phase generated by the clock (not shown). Corresponding signals passed through the other devices within DCDC amplifier 400 are also labeled with corresponding P and N letters to indicate that the generated signals relate to the original OUTP and OUTN phases (or INP and INN clock signals generated by a clock of previous device coupled to inputs of DCDC amplifier).

Correction circuit 420 comprises low pass filter 430 and error correction amplifier 440, each receiving a differential input and producing a differential output. Input nodes of low pass filter 430 are respectively coupled to OUTP 415 and OUTN 417 of differential output clock wires 410. With these inputs, low pass filter 430 generates a pair of differential error outputs, ERROR_P 435 and ERROR_N 437. Low pass filter 430 senses the DC offset in the received differential output signals (415/417), filters these DC offsets out of the differential output signals (415/417), then forwards these DC offsets as respective error outputs (435/437) to error correction amplifier 440.

Error correction amplifier 440 is a differential current steering circuit that produces differential feedback outputs, FEEDBACK_P 445 and FEEDBACK_N 447, which are summed (dotted) into respective differential output signals (415/417) to produce a corrected differential output 415′/417′. As shown, correction circuit 420 (via error correction amplifier 440) provides DC correction voltages directly to differential outputs (415/417) rather than a feedback to amplifier itself.

As illustrated, error correction amplifier 440 comprises two N-channel transistors, coupled at their sources to a current source and at their drains to respective ones of differential output signal wires 410. N-channel transistors may be any type of transistor, e.g., field effect transistors (FETs) or CMOS FETS. Notably, also, one alternate embodiment of the invention may utilize P-channel transistors. With this alternate embodiment, the polarities of the error signals are inverted such that the P-channel transistors may turn on for relative sizes of negative DC voltages.

Each transistor is coupled at its gate input to one of the two error outputs (435/437) from low pass filter 430. The relative size of each error output (435/437) determines/influences the amount of current flow through each transistor (as the gate input turns the transistor on). This current flow in turn determines the amount of correction current provided to the particular output signal (415/417) connected to the transistor's source terminal.

Error correction amplifier 440 thus provides two correction currents, CORRECTION_P 445 and CORRECTION_N 447, each dotted into respective outputs, OUTP 415 and OUTN 417. Each correction current is the inverse of and proportional to the DC offset of the respective output signal (415/417). In the illustrative embodiment, the correction current is out of phase (180 degrees) with the DC offset from the differential output signal (415/417), so that the correction current operates to pull the DC offset (up or down) to a zero. The DC-level comparison by error correction amplifier 440 forces the average DC level of error signals 435/437 to be substantially equal (i.e., zero differential voltage). By bringing the DC offset in the error signals 435/437 to zero, the correction current boosts the small pulses (417) on the differential output wires 410 and shrinks the large pulses (415) on the differential output wires 410 so that the overall duty-cycle is improved.

The differential amplifier 405 may be any normal amplifier with normal differential tail current and resistor loads. Error correction amplifier 440 is a scaled down version of differential amplifier 405 having similar components (transistors and resistors). The error correction amplifier 440 is connected in such a way that the feedback signals 445/447 are 180 degrees out of phase with buffer output signals (415/417). Thus, OUTP 415 connects to inverted (negative) FEEDBACK_N 447 and OUTN 417 connects to inverted (positive) FEEDBACK_P 445. This pulls the output pulse that has the higher (relative) DC component down while the output pulse with the lower DC component is pulled up until both sides average approximately the same up time. The differential DC current from the output (445/447) of the correction amplifier is inverted to effectively remove the DC offset in buffer output signals (415/417) caused by duty-cycle distortion.

Notably, the feedback current provided is a differential pair of currents. The invention provides a “completely differential” approach to correcting the problems with duty-cycle distortions by introducing the DCDC amplifier, which includes a standard differential amplifier with output wires coupled to an input and an output of a correction circuit. All components of the correction circuit are differential and receive differential inputs and produce a differential output. No complementary signals are required. By implementing the completely differential approach, the differential feedback currents required are small. The voltage produced by the feedback currents is substantially smaller (e.g., 10's of millivolts) than would be required for an implementation utilizing complementary signals (100s of millivolts for switching). Also, by providing a completely differential approach, the resulting circuit requires a smaller number of stages, reduces power consumption, required area, and error.

As shown by FIG. 4, all circuitry is differential so that no single-ended or conversion circuits are required. Also, the circuit of the invention is very compact in design, and thus utilizes low power and requires very little area. In one embodiment, simple circuits that are compact in area and low in power consumption are utilized to create the correction circuit. Also, the output impedance of the clock buffer is used by the correction circuit currents to correct the average DC offset caused by duty-cycle distortion, thus saving area. This space efficient design provides a great benefit when utilized in a standard circuit book that has numerous instances on a chip.

The addition of this differential feedback correction to a differential amplifier output enables the DCDC amplifier's correction circuit to dynamically analyze the duty-cycle of the amplifier's output and then adjust the output to correct the duty-cycle of the same and subsequent outputs. The design recognizes that a differential clock duty-cycle distortion has an average DC voltage offset between the positive and negative legs of the signal, and the design enables the average DC offset to be negated with the correction circuit, thus removing a substantial portion of the duty-cycle distortion.

FIG. 5 illustrates the correction of differential clock signals 515/517 propagating through correction circuit 420, which is illustrated by FIG. 4 and described above. Each differential signal of the clock has two differential clock signals represented in FIG. 5 as a positive input, NP 515, on an up clock (Tup), which is illustrated by solid lines, and as a negative input, INN 517, on a down clock (Tdown) illustrated by dashed lines. According to the illustrated embodiment, Tup of INP 515 is a longer fraction of the clock period than Tdown of INN 517, as indicated by the relative length of time for each clock signal. The corresponding frequency component (Tdown) of INN 517 is higher than the frequency component (Tup) of INP 515. Also, the difference in up pulse time versus down pulse time correlates to a corresponding difference in DC component for INP 515 and INN 517. The longer up time corresponds to a higher DC component for INP 515 and the longer down time corresponds to a lower DC component for INN 517.

The differential input signals, NP 515 and INN 517 (corresponding to output signals, OUTP 415 and OUTN 417 of FIG. 4) pass through low pass filter 430, which filters out the alternating components of each signal and forwards only the DC components of each signal, ERROR_P 525 and ERROR_N 527 to error correction amplifier 440. These error outputs represent the average DC offset of the differential signals (515/517). Sensing of the DC offset is performed by filtering the differential signals (515/517) through low-pass filter 430 in order to remove as much higher frequency (alternating) components as possible. This filtering results in the average DC differential voltage of the differential signals (515/517), which approximates the duty-cycle distortion.

As shown, the error outputs are received at error correction amplifier 440, which generates correction/offset currents (FEEDBACK_P and FEEDBACK_N). These correction offset currents are generated by amplifying the filtered output signals (i.e., DC error outputs) and then passing these error outputs to error correction amplifier 440. The outputs of this correction amplifier stage are dotted (summed) into respective buffer output signals (415/417) propagating on amplifier output wires 410′ with negative polarity in order to provide negative correction currents (“feedback”). The negative correction currents reduces the high DC component while increasing the low DC component, resulting in correction of the duty-cycle within corrected output signals 515′/517′. As shown, the resulting relative pulse widths of both pulses (Tup and Tdown) are closer to being equal than when first inputted to low pass filter 430. Accordingly, the wider pulse (Tup) becomes shorter so that the up time is less, while the more narrow pulse (Tdown) becomes longer so that its up time is larger. Changes to the signal magnitudes may be on the order of 10's of millivolts.

All existing prior art approaches utilizes single-ended clocking, where the duty-cycle measurement is completed by comparing a DC average of a single ended clock to either a fixed reference voltage (DAC or voltage divider) or a complementary clock's DC average. Also, the duty-cycle correction is completed with single-ended signals. Such measurements have much more error than a truly-differential comparison of a differential signal, as described herein. Also, a majority of conventional feedback approaches to duty-cycle correction utilizes conversion circuits.

The present invention utilizes small-signal differential circuits to correct the duty-cycle. This differential approach is better at rejecting noise. Additionally, the present design has much better matching across product variations. Thus, unlike conventional feedback approaches, which utilize single-ended circuits (e.g., a single-ended reference and feedback voltage) and comparisons of complementary inputs to provide a single-ended feedback voltage, which are both prone to noise, the present invention provides a design by which a comparison is made of the differential outputs of the amplifier and a differential correction current is summed directly into the output of the amplifier.

One additional benefit of the present “completely differential” approach is that there is no requirement that the circuits convert between differential and single-ended signaling, since the present “completely differential” approach does not require the additional single-ended or conversion circuits. This reduces the total number of circuit stages required, reducing area and sources of noise. The completely differential approach also substantially eliminates the problems with such conventional circuits, which have inherent problems of poor noise rejection, duty-cycle distortion, higher power requirements, and increased area for added circuitry.

As a final matter, it is important that while an illustrative embodiment of the present invention has been, and will continue to be, described in the context of a fully functional computer system with installed management software, those skilled in the art will appreciate that the software aspects of an illustrative embodiment of the present invention are capable of being distributed as a program product in a variety of forms, and that an illustrative embodiment of the present invention applies equally regardless of the particular type of signal bearing media used to actually carry out the distribution. Examples of signal bearing media include recordable type media such as floppy disks, hard disk drives, CD ROMs, and transmission type media such as digital and analogue communication links.

While the invention has been particularly shown and described with reference to a preferred embodiment, it will be understood by those skilled in the art that various changes in form and detail may be made therein without departing from the spirit and scope of the invention.

1. An electrical circuit device comprising:
a differential amplifier receiving a differential clock input and providing a differential clock output on a pair of output wires;
a correction circuit that automatically corrects duty-cycle distortions in the differential clock output generated by the differential amplifier utilizing a differential correction mechanism;
wherein the correction circuit comprises a pair of inputs coupled to respective ones of the pair of output wires and a pair of outputs coupled to said respective ones of the pair of output wires and which receives the differential clock output at the pair of inputs and generates a pair of differential correction currents, one on each of the pair of outputs, whereby distortions in a duty-clock cycle of the differential clock outputs are automatically corrected by the respective differential correction current.

2. (canceled)

3. The device of claim 1, wherein said correction circuit comprises:
a differential low pass filter having the pair of inputs as its input terminals and which filters the differential clock output to produce a pair of inverted, differential direct current (DC) offsets from respective pulses within the differential clock output; and
a correction amplifier coupled to differential outputs of the low pass filter, said correction amplifier comprising circuit elements for receiving the DC offsets from the low pass filter and generating a proportionate correction current that is passed as the differential correction current to the respective outputs of the pair of outputs.

4. The device of claim 3, wherein the correction amplifier is a scaled down version of the differential amplifier.

5. The device of claim 3, wherein the correction amplifier comprises a pair of transistors, each having a gate terminal coupled to one of the DC offsets, a source terminal coupled to a current source, and a drain terminal coupled to a respective one of the output wires.

6. The device of claim 3, wherein the correction amplifier inverts the value of the differential correction current relative to the DC value of the differential clock output.

7. The device of claim 6, wherein a negative differential correction current is applied to the differential clock output signal with the larger DC value and a positive differential correction current is applied to the differential clock output signal with the smaller DC value.

8. The device of claim 1, wherein the device is an application specific integrated circuit (ASIC).

9. A method for fabricating a duty-cycle distortion correction (DCDC) differential amplifier according to claim 1.

10. An application specific integrated circuit (ASIC) comprising:
a clock source providing a differential clock signal; and
a duty-cycle distortion correction (DCDC) differential amplifier that automatically corrects duty-cycle distortions in the clock signal propagating through the DCDC differential amplifier via a differential correction mechanism;
wherein said DCDC differential amplifier includes a differential correction circuit having a pair of inputs coupled to respective ones of the pair of output wires and a pair of outputs coupled to said respective ones of the pair of output wires and which receives the differential clock output at the pair of inputs and generates a pair of differential correction currents, one on each of the pair of outputs, whereby distortions in a duty-clock cycle of the differential clock outputs are automatically corrected by the respective differential correction current.

11. The ASIC of claim 10, said DCDC differential amplifier further comprising:
a differential amplifier receiving an input of the differential clock signal and providing a differential clock output on a pair of output wires.

12. The ASIC of claim 11, wherein said differential correction circuit comprises:
a differential low pass filter having the pair of inputs as its input terminals and which filters the differential clock output to produce a pair of inverted, differential DC offsets from respective pulses within the differential clock output; and
a correction amplifier coupled to differential outputs of the low pass filter, said correction amplifier comprising circuit elements for receiving the DC offsets from the low pass filter and generating a proportionate correction current that is passed as the differential correction current to the respective outputs of the pair of outputs.

13. The ASIC of claim 12, wherein the correction amplifier is a scaled down version of the differential amplifier.

14. The ASIC of claim 12, wherein:
the correction amplifier comprises a pair of transistors, each having a gate terminal coupled to one of the DC offsets, a source terminal coupled to a current source, and a drain terminal coupled to a respective one of the output wires; and
each correction current is generated via application of the respective DC offset to the gate terminal of the transistor and is proportionate in magnitude to the magnitude of the applied DC offset.

15. The ASIC of claim 12, wherein the correction amplifier inverts the value of the differential correction current relative to the DC value of the differential clock output.

16. The ASIC of claim 15, wherein a negative differential correction current is applied to the differential clock output signal with the larger DC value and a positive differential correction current is applied to the differential clock output signal with the smaller DC value.

17. The processor chip of claim 9, further comprising:
entry dispatching logic associated with the store queue for selectively dispatching an entry of said store queue to enable the entry to be re-allocated to a next set of store operations; and
signaling logic associated with said entry dispatch logic for asserting a pop signal to said tracking logic.

17. A method for fabricating the ASIC of claim 10.

18. A method for correcting distortions in duty-cycle of a propagating clock in an amplifier circuit, said method comprising:
receiving from a differential amplifier a copy of a differential output clock signal propagating on differential output wires of the differential amplifier, wherein the differential amplifier receives a differential input clock signal and generates the differential output clock signal on the differential output wires, wherein said differential amplifier includes a differential correction circuit having a pair of inputs coupled to respective ones of the pair of output wires and a pair of outputs coupled to said respective ones of the pair of output wires and which receives the differential clock output at the pair of inputs and generates a pair of differential correction currents, one on each of the pair of outputs, whereby distortions in a duty-clock cycle of the differential clock outputs are automatically corrected by the respective differential correction current;
passing the received differential output clock signal through a differential low pass filter having two inputs, one coupled to each of the differential output wires, and which filters out alternating frequency components of the differential output clock signal to produce a pair of DC offset currents each corresponding to individual signals of the differential output clock; and
coupling the pair of DC offset current outputs to respective gates of a pair of correction transistors such that the DC offset current turn on said pair of correction transistors;
wherein the transistors each generate an inverted correction current that is dotted into respective ones of the differential output wires to correct a distortion in the duty-cycle of the differential output clock.

19. The method of claim 18, further comprising inverting a value of the correction current relative to the differential clock output signals, wherein a negative differential correction current is applied to the differential clock output signal with the larger DC value and a positive differential correction current is applied to the differential clock output signal with the smaller DC value.
